(19) United States
(12) Patent Application Publication
(10) Pub. No.: US 2011/0130989 A1
(43) Pub. Date: Jun. 2, 2011

(54) SYSTEM AND METHOD FOR IDENTIFYING A PERIPHERAL COMPONENT INTERCONNECT EXPRESS SIGNAL

(75) Inventors: HUANG-CHING LU, Tu-Cheng (TW); WANG-DING SU, Tu-Cheng (TW); JUI-HSIUNG HO, Tu-Cheng (TW)

(73) Assignee: HON HAI PRECISION INDUSTRY CO., LTD., Tu-Cheng (TW)

(21) Appl. No.: 12/762,380

(22) Filed: Apr. 19, 2010

(30) Foreign Application Priority Data
Nov. 27, 2009 (CN) 200910310577.1

(51) Int. Cl. G06F 19/00; G06F 13/36; G01R 29/00

(52) U.S. Cl. 702/66; 710/314

(57) ABSTRACT

A system and method for identifying a peripheral component interconnect express (PCIe) signal obtains a waveform of the PCIe signal. A pre-emphasis value of the PCIe signal is calculated according to the waveform. Accordingly, a signal type of the PCIe signal is determined.

### BACKGROUND

1. Technical Field

Embodiments of the present disclosure relate to signal test systems and methods, and particularly to a system and method for identifying a peripheral component interconnect express (PCIe) signal.

2. Description of Related Art

A peripheral component interconnect express (PCIe) device (e.g., a motherboard) can generate different PCIe signals, such as a PCIe 2.X signal with 3.5 dB pre-emphasis and a PCIe 2.X signal with 6.0 dB pre-emphasis. In order to test the PCIe signals correctly, signal types of the PCIe signals are desired to be determined in advance.

### BRIEF DESCRIPTION OF THE DRAWINGS

FIG. 1 is a block diagram of one embodiment of an application environment of a system for identifying a PCIe signal.

FIG. 2 is a block diagram of a signal identification unit in FIG. 1.

FIG. 3 is a flowchart of one embodiment of a method for identifying a PCIe signal implementing a system, such as that in FIG. 1.

FIG. 4 illustrates one exemplary waveform of the PCIe signal.

### DETAILED DESCRIPTION

In general, the word “module,” as used herein, refers to logic embodied in hardware or firmware, or to a collection of software instructions, written in a program language. In one embodiment, the program language may be Java or C. One or more software instructions in the modules may be embedded in firmware, such as an EPROM. The modules described herein may be implemented as either software and/or hardware modules and may be stored in any type of computer-readable medium or other storage device.

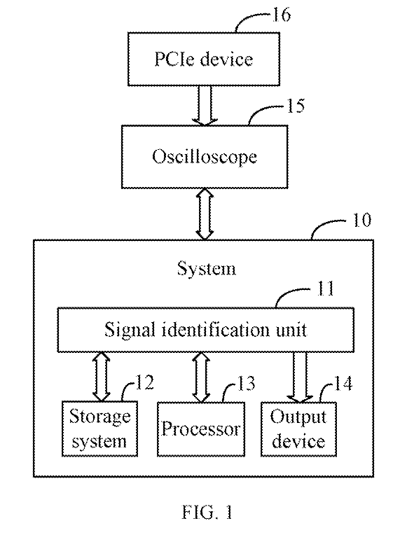

FIG. 1 is a block diagram of one embodiment of an application environment of a system 10 for identifying a peripheral component interconnect express (PCIe) signal from a PCIe device 16. The system 10 may be used to identify a signal type of the PCIe signal before the PCIe signal is performance tested. In one embodiment, the system 10 is connected to an oscilloscope 15 and the PCIe device 16 in series. The PCIe device 16 may be an electronic device (e.g., a motherboard) that generates different PCIe signals, such as a PCIe 2.X signal with 3.5 dB pre-emphasis and a PCIe 2.X signal with 6.0 dB pre-emphasis, for example. The PCIe signals may be output to another PCIe device. The system 10 may be a data processing device or a computerized device such as a personal computer, an application server, or a workstation, for example.

The system 10 may include a signal identification unit 11, a storage system 12, a processor 13, and an output device 14. One or more computerized codes of the signal identification unit 11 may be stored in the storage system 12 and executed by the processor 13. In one embodiment, the storage system 12 may be a memory, a hard disk, or a compact disk. The output device 14 may be a display screen or a printer, which outputs the signal type of the PCIe signal to a user.

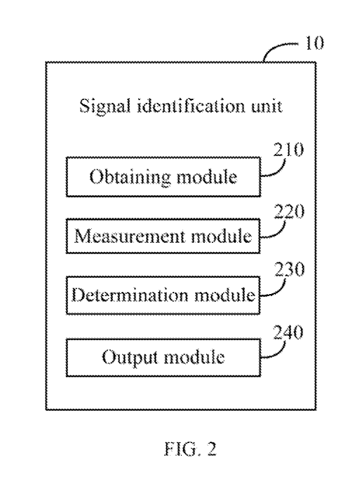

FIG. 2 is a block diagram of one embodiment of the signal identification unit 11 in FIG. 1. In one embodiment, the signal identification unit 11 may include an obtaining module 210, a measurement module 220, a determination module 230, and an output module 240.

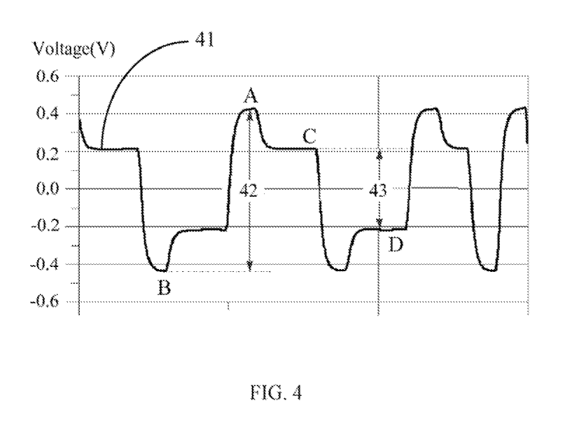

The obtaining module 210 obtains a waveform of the PCIe signal from the PCIe device 16. As mentioned above, the PCIe signal may be generated by the PCIe device 16 and output to another PCIe device. In one embodiment, the obtaining module 210 may control the oscilloscope 15 to obtain the waveform from the PCIe device 16. FIG. 4 illustrates one exemplary waveform 41 of the PCIe signal.

The measurement module 220 calculates a pre-emphasis value of the PCIe signal according to the waveform. In one embodiment, the measurement module 220 may measure a peak voltage difference and a steady-state voltage difference of the PCIe signal according to the waveform. According to the peak voltage difference and the steady-state voltage difference, the measurement module 220 calculates the pre-emphasis value of the PCIe signal. With respect to FIG. 4, a peak voltage difference 42 is a difference between a positive peak voltage “A” and a negative peak voltage “B” of the PCIe signal. A steady-state voltage difference 43 is a difference between a positive steady-state voltage “C” and a negative steady-state voltage “D” of the PCIe signal. Further details are disclosed below.

The determination module 230 determines the signal type of the PCIe signal according to the calculated pre-emphasis value. The determination module 230 may compare the calculated pre-emphasis value of the PCIe signal with a standard pre-emphasis value of a specific PCIe signal to identify the signal type of the PCIe signal. In one embodiment, if a difference between the calculated pre-emphasis value of the PCIe signal and the standard pre-emphasis value of the specific PCIe signal is less than a predetermined amount, such as 0.5 dB, the determination module 230 determines that the signal type of the PCIe signal is the specific PCIe signal. For example, a standard pre-emphasis value of one kind of PCIe 2.X signal is 3.5 dB. If the calculated pre-emphasis value is in a range from 3.0 dB to 4.0 dB, the PCIe signal is considered to be a PCIe 2.X signal with 3.5 dB pre-emphasis.

The output module 240 outputs the signal type of the PCIe signal to the output device 14. In one embodiment, the output module 240 displays the signal type on a display screen.

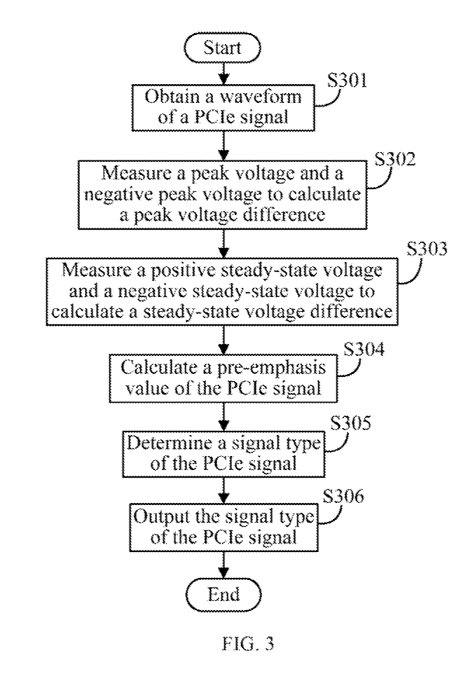

FIG. 3 is a flowchart of one embodiment of a method for identifying a PCIe signal implementing a system, such as that in FIG. 1. The method may be used to identify a signal type of the PCIe signal before the PCIe signal is performance tested. Depending on the embodiments, additional blocks may be added, others removed, and the ordering of the blocks may be changed.

In block S301, the obtaining module 210 obtains a waveform of the PCIe signal from the PCIe device 16. In one embodiment, the obtaining module 210 may control the oscilloscope 15 to obtain the waveform of the PCIe signal. The obtaining module 210 may send a waveform capture command to the oscilloscope 15. In response to the waveform capture command, the oscilloscope 15 captures the waveform from the PCIe device 16, and sends the waveform to the obtaining module 210. FIG. 4 illustrates one exemplary waveform 41 of the PCIe signal.

In block S302, the measurement module 220 measures a positive peak voltage and a negative peak voltage of the PCIe signal according to the waveform. The measurement module 220 calculates a peak voltage difference of the PCIe signal by subtracting the negative peak voltage from the positive peak voltage. In one embodiment with respect to FIG. 4, “A” denotes the positive peak voltage of the PCIe signal, which is 0.43V. “B” denotes the negative peak voltage of the PCIe signal, which is −0.43V. Accordingly, the peak voltage difference 42 is 0.86V.

In block S303, the measurement module 220 measures a positive steady-state voltage and a negative steady-state voltage of the PCIe signal according to the waveform. The measurement module 220 calculates a steady-state voltage difference of the PCIe signal by subtracting the negative steady-state voltage from the positive steady-state voltage. In one embodiment with respect to FIG. 4, “C” denotes the positive steady-state voltage, which is 0.21V. “D” denotes the negative steady-state voltage, which is −0.21V. Accordingly, the steady-state voltage difference 43 is 0.42V.

In block S304, the measurement module 220 calculates a pre-emphasis value according to the peak voltage difference and the steady-state voltage difference. One embodiment of a formula to calculate the pre-emphasis value may be as follows: 20×Lg(D1/D2), where “D1” denotes the peak voltage difference, “D2” denotes the steady-state voltage difference, “Lg” denotes a base-10 logarithm. For example, if the peak voltage difference is 0.86V and the steady-state voltage is 0.42V, the pre-emphasis is 20×Lg(0.86/0.42)≈6 dB.

In block S305, the determination module 230 determines a signal type of the PCIe signal according to the calculated pre-emphasis value. In one embodiment, if a difference between the calculated pre-emphasis value of the PCIe signal and a standard pre-emphasis value of a specific PCIe signal is less than a predetermined amount, such as 0.5 dB, the determination module 230 determines that the signal type of the PCIe signal is the specific PCIe signal. In one example, a standard pre-emphasis value of one kind of PCIe 2.X signal is 3.5 dB. If the calculated pre-emphasis value is in a range from 3.0 dB to 4.0 dB, the PCIe signal is considered to be a PCIe 2.X signal with 3.5 dB pre-emphasis. In another example, a standard pre-emphasis value of another kind of PCIe 2.X signal is 6.0 dB. If the calculated pre-emphasis value is in a range from 5.5 dB to 6.5 dB, the PCIe signal is considered to be a PCIe 2.X signal with 6.0 dB pre-emphasis.

In block S306, the output module 240 outputs the signal type of the PCIe signal to the output device 14. In one embodiment, the output device 14 is a display screen. Accordingly, the output module 240 displays the signal type, such as PCIe 2.X with 3.5 dB pre-emphasis on the display screen.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A system for identifying a peripheral component interconnect express (PCIe) signal, the system comprising:
a storage system;
at least one processor; and
a signal identification unit being stored in the storage system and executable by the at least one processor, the signal identification unit comprising:
an obtaining module operable to obtain a waveform of the PCIe signal from a PCIe device;
a measurement module operable to calculate a pre-emphasis value of the PCIe signal according to the waveform;
a determination module operable to determine a signal type of the PCIe signal according to the pre-emphasis value; and
an output module operable to output the signal type of the PCIe signal to an output device.

2. The system of claim 1, wherein the obtaining module controls an oscilloscope to obtain the waveform of the PCIe signal.

3. The system of claim 1, wherein the measurement module calculates the pre-emphasis value of the PCIe signal by:
measuring a peak voltage difference and a steady-state voltage difference of the PCIe signal according to the waveform; and
calculating the pre-emphasis value of the PCIe signal according to the peak voltage difference and the steady-state voltage difference.

4. The system of claim 1, wherein the determination module compares the pre-emphasis value of the PCIe signal with a standard pre-emphasis value of a specific PCIe signal to determine the signal type of the PCIe signal.

5. The system of claim 1, wherein the output device is a display screen or a printer.

6. A method for identifying a peripheral component interconnect express (PCIe) signal, the method comprising:
obtaining a waveform of the PCIe signal from a PCIe device;
calculating a pre-emphasis value of the PCIe signal according to the waveform;
determining a signal type of the PCIe signal according to the pre-emphasis value; and
outputting the signal type of the PCIe signal to an output device.

7. The method of claim 6, wherein the waveform of the PCIe signal is obtained by an oscilloscope.

8. The method of claim 6, wherein the pre-emphasis value of the PCIe signal is calculated by:
measuring a peak voltage difference and a steady-state voltage difference of the PCIe signal according to the waveform; and
calculating the pre-emphasis value of the PCIe signal according to the peak voltage difference and the steady-state voltage difference.

9. The method of claim 6, wherein the signal type of the PCIe signal is determined by comparing the pre-emphasis value of the PCIe signal with a standard pre-emphasis value of a specific PCIe signal.

10. The method of claim 6, wherein the output device is a display screen or a printer.

11. A computer-readable medium having stored thereon instructions that, when executed by a computerized device, causes the computerized device to execute a method for identifying a peripheral component interconnect express (PCIe) signal, the method comprising:
obtaining a waveform of the PCIe signal from a PCIe device;
calculating a pre-emphasis value of the PCIe signal according to the waveform;
determining a signal type of the PCIe signal according to the pre-emphasis value; and
outputting the signal type of the PCIe signal to an output device.

12. The medium of claim 11, wherein the waveform of the PCIe signal is obtained by an oscilloscope.

13. The medium of claim 11, wherein the pre-emphasis value of the PCIe signal is calculated by:
measuring a peak voltage difference and a steady-state voltage difference of the PCIe signal according to the waveform; and
calculating the pre-emphasis value of the PCIe signal according to the peak voltage difference and the steady-state voltage difference.

14. The medium of claim 11, wherein the signal type of the PCIe signal is determined by comparing the pre-emphasis value of the PCIe signal with a standard pre-emphasis value of a specific PCIe signal.

15. The medium of claim 11, wherein the output device is a display screen or a printer.
